(19) United States
(12) Patent Application Publication
(10) Pub. No.: US 2024/0297120 A1
(43) Pub. Date: Sep. 5, 2024

(54) SEMICONDUCTOR PACKAGE STRUCTURE

(71) Applicant: MEDIATEK INC., Hsinchu City (TW)

(72) Inventors: Wei-Yu CHEN, Hsinchu City (TW); Yi-Lin TSAI, Hsinchu City (TW); Nai-Wei LIU, Hsinchu City (TW); Shih-Chin LIN, Hsinchu City (TW); Wen-Sung HSU, Hsinchu City (TW)

(21) Appl. No.: 18/407,783

(22) Filed: Jan. 9, 2024

Related U.S. Application Data
(60) Provisional application No. 63/488,205, filed on Mar. 3, 2023.

(51) Int. Cl. H01L 23/538; H01L 23/00; H01L 23/31; H01L 23/498; H01L 25/10; H01L 25/16

(52) U.S. Cl. CPC H01L 23/5381; H01L 23/3135; H01L 23/49811; H01L 23/49822; H01L 23/49838; H01L 24/16; H01L 24/32; H01L 24/73; H01L 25/105; H01L 25/16; H01L 2224/16227; H01L 2224/16238; H01L 2224/32225; H01L 2224/73204; H01L 2924/19011; H01L 2924/19106

(57) ABSTRACT

A semiconductor package structure includes a first redistribution layer, a first semiconductor die, a second semiconductor die, a bridge structure, and a plurality of conductive bumps. The first semiconductor die and the second semiconductor die are disposed over the first redistribution layer. The bridge structure is disposed under the first redistribution layer. The first semiconductor die is electrically coupled to the second semiconductor die through the first redistribution layer and the bridge structure. The conductive bumps are disposed under the first redistribution layer and are coupled to the first redistribution layer. The bridge structure is disposed between at least two of the conductive bumps.

### CROSS REFERENCE TO RELATED APPLICATIONS

This application claims the benefit of U.S. Provisional Application No. 63/488,205 filed on Mar. 3, 2023, the entirety of which is incorporated by reference herein.

### BACKGROUND OF THE INVENTION

### Field of the Invention

The present invention relates to semiconductor technology, and, in particular, to a semiconductor package structure including a bridge structure.

### Description of the Related Art

In addition to providing a semiconductor die with protection from environmental contaminants, a semiconductor package structure can also provide an electrical connection between the semiconductor die packaged inside it and a substrate such as a printed circuit board (PCB).

Although existing semiconductor package structures generally meet requirements, they have not been satisfactory in all respects. For example, manufacturing semiconductor package structures for die to die talk and chiplet integration is usually complex, leading to high cost and low yield rate. Therefore, further improvements in semiconductor package structures are required.

### BRIEF SUMMARY OF THE INVENTION

Semiconductor package structures are provided. An exemplary embodiment of a semiconductor package structure includes a first redistribution layer, a first semiconductor die, a second semiconductor die, a bridge structure, and a plurality of conductive bumps. The first semiconductor die and the second semiconductor die are disposed over the first redistribution layer. The bridge structure is disposed under the first redistribution layer. The first semiconductor die is electrically coupled to the second semiconductor die through the first redistribution layer and the bridge structure. The conductive bumps are disposed under the first redistribution layer and are coupled to the first redistribution layer. The bridge structure is disposed between at least two of the conductive bumps.

Another embodiment of a semiconductor package structure includes a substrate, a redistribution layer, a plurality of conductive bumps, a bridge structure, a first semiconductor die, and a second semiconductor die. The conductive bumps are disposed between the substrate and the redistribution layer and electrically couple the substrate and the redistribution layer. The bridge structure is disposed between the substrate and the redistribution layer and is electrically coupled to the redistribution layer. The bridge structure is spaced apart from the substrate. The first semiconductor die and the second semiconductor die are disposed over the redistribution layer and are electrically coupled to the bridge structure. The first semiconductor die is electrically coupled to the second semiconductor die through the first redistribution layer and the bridge structure.

Yet another embodiment of a semiconductor package structure includes a first redistribution layer, a first semiconductor die, a second semiconductor die, a molding material, and a bridge structure. The first semiconductor die and the second semiconductor die are disposed over the first redistribution layer. The molding material surrounds the first semiconductor die and the second semiconductor die. The bridge structure is disposed under the first redistribution layer and electrically couples the first semiconductor die and the second semiconductor die. A bottom surface of the bridge structure is exposed. The bottom surface of the bridge structure is a surface facing away from the first redistribution layer.

### BRIEF DESCRIPTION OF THE DRAWINGS

The present invention can be more fully understood by reading the subsequent detailed description and examples with references made to the accompanying drawings, wherein:

FIGS. 1A-1D are cross-sectional views of various stages of manufacturing an exemplary semiconductor package structure in accordance with some embodiments of the present disclosure;

FIG. 2 is a cross-sectional view of an exemplary bridge structure in accordance with some embodiments of the present disclosure;

FIGS. 3A-3B are cross-sectional views of various stages of manufacturing an exemplary semiconductor package structure in accordance with some embodiments of the present disclosure; and

FIGS. 4A-4D are cross-sectional views of various stages of manufacturing an exemplary semiconductor package structure in accordance with some embodiments of the present disclosure.

### DETAILED DESCRIPTION OF THE INVENTION

The following description is made for the purpose of illustrating the general principles of the invention and should not be taken in a limiting sense. The scope of the invention is best determined by reference to the appended claims.

The present disclosure will be described with respect to particular embodiments and with reference to certain drawings, but the disclosure is not limited thereto and is only limited by the claims. The drawings described are only schematic and are non-limiting. In the drawings, the size of some of the elements may be exaggerated for illustrative purposes and not drawn to scale. The dimensions and the relative dimensions do not correspond to actual dimensions in the practice of the disclosure.

Additional elements may be added on the basis of the embodiments described below. For example, the description of “a first element on/over a second element” may include embodiments in which the first element is in direct contact with the second element, and may also include embodiments in which additional elements are disposed between the first element and the second element such that the first element and the second element are not in direct contact.

The spatially relative descriptors of the first element and the second element may change as the structure is operated or used in different orientations. In addition, the present disclosure may repeat reference numerals and/or letters in the various embodiments. This repetition is for simplicity and clarity and does not in itself dictate a relationship between the various embodiments discussed.

A semiconductor package structure including a bridge structure is described in accordance with some embodiments of the present disclosure. The bridge structure is disposed on a surface of a redistribution layer where conductive bumps are disposed. As a result, the layer count of the redistribution layer can be reduced, and thus yield improvement, cost saving and scalability of the semiconductor package structure can be achieved.

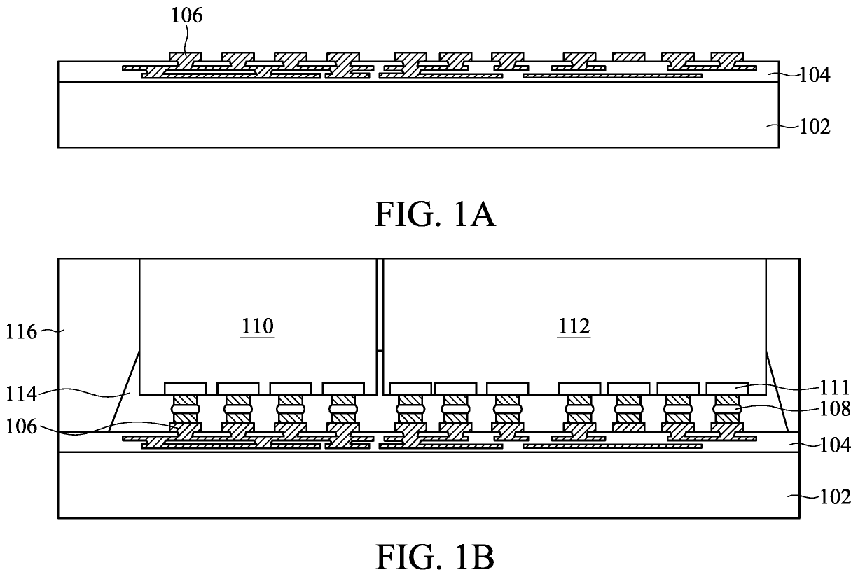

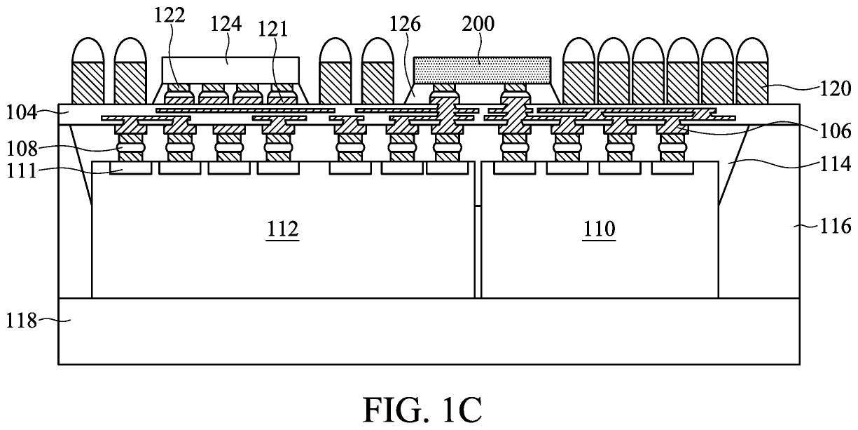

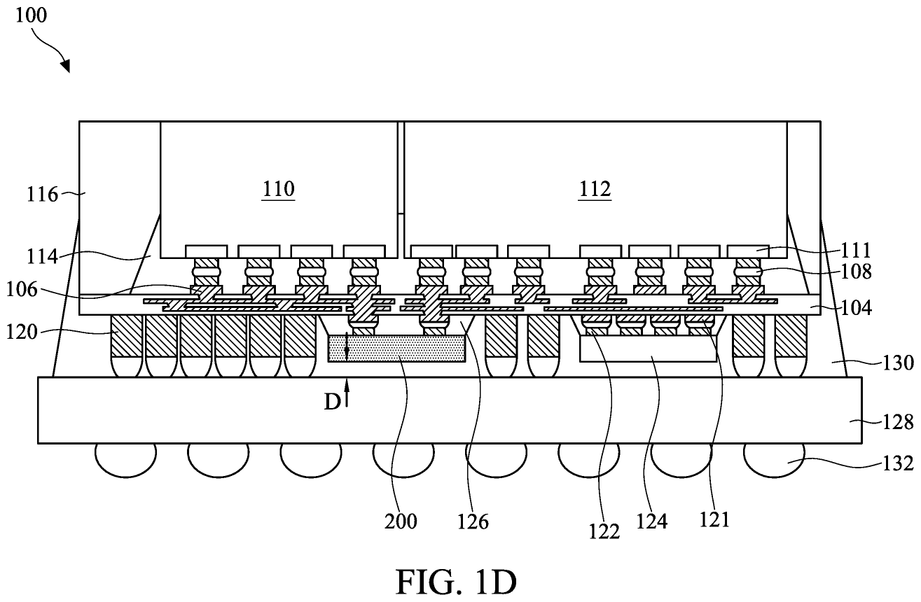

FIGS. 1A-1D are cross-sectional views of various stages of manufacturing a semiconductor package structure 100 in accordance with some embodiments of the present disclosure. Additional features can be added to the semiconductor package structure 100. Some of the features described below can be replaced or eliminated for different embodiments. To simplify the diagram, only a portion of the semiconductor package structure 100 is illustrated.

As illustrated in FIG. 1A, a redistribution layer 104 is formed over a carrier wafer 102, in accordance with some embodiments. The carrier wafer 102 may be a glass carrier substrate, a ceramic carrier substrate, or another suitable carrier substrate.

The redistribution layer 104 may have a plurality of dielectric layers and at least one conductive layer. The redistribution layer 104 may have a plurality of conductive vias disposed in the dielectric layer and connected to a conductive wire or a conductive section in the conductive layer. The precise patterns of the conductive layer are defined using photolithography technology, followed by an etching process to remove the excess metal, leaving the desired conductive wires and the conductive sections. For example, the redistribution layer 104 includes two or three conductive layers. The conductive layers may be formed of metal, such as tungsten, titanium, tantalum, ruthenium, cobalt, copper, aluminum, platinum, tin, silver, gold, the like, an alloy thereof, or a combination thereof. The dielectric layers may be formed of polymer, including polyimide (PI), polybenzoxazole (PBO), benzocyclobutene (BCB), epoxy, the like, or a combination thereof. Alternatively, the dielectric layers may be formed of silicon oxide, silicon nitride, silicon oxynitride, the like, or a combination thereof.

Then, a plurality of conductive pads 106 are formed over the redistribution layer 104 and electrically coupled to the redistribution layer 104, in accordance with some embodiments. Specifically, the conductive pads 106 are electrically coupled to the conductive vias in the redistribution layer 104. The conductive pads 106 may be formed of metal, such as tungsten, titanium, tantalum, ruthenium, cobalt, copper, aluminum, platinum, tin, silver, gold, the like, an alloy thereof, or a combination thereof.

Afterwards, as illustrated in FIG. 1B, a first semiconductor die 110 and a second semiconductor die 112 are disposed over the redistribution layer 104, in accordance with some embodiments. The first semiconductor die 110 and the second semiconductor die 112 may include a plurality of conductive pads 111 on the frontside of the first semiconductor die 110 and the frontside of the second semiconductor die 112. The conductive pads 111 may be formed of metal, such as tungsten, titanium, tantalum, ruthenium, cobalt, copper, aluminum, platinum, tin, silver, gold, the like, an alloy thereof, or a combination thereof.

The first semiconductor die 110 and the second semiconductor die 112 may be electrically coupled to the redistribution layer 104 through a plurality of conductive bumps 108 and the conductive pads 106. In some embodiments, the conductive bumps 108 include microbumps on the conductive pads 111 and microbumps on the conductive pads 106 and include solder materials connecting the microbumps on the conductive pads 111 and microbumps on the conductive pads 106. The conductive bumps 108 may be formed of metal, such as tungsten, titanium, tantalum, ruthenium, cobalt, copper, aluminum, platinum, tin, silver, gold, the like, an alloy thereof, or a combination thereof.

In some embodiments, the first semiconductor die 110 and the second semiconductor die 112 each includes a system-on-chip (SoC) die, a logic device, a memory device, a radio frequency (RF) device, the like, or any combination thereof. For example, the first semiconductor die 110 and the second semiconductor die 112 may each include a micro control unit (MCU) die, a microprocessor unit (MPU) die, a power management integrated circuit (PMIC) die, a radio frequency front end (RFFE) die, an accelerated processing unit (APU) die, a central processing unit (CPU) die, a graphics processing unit (GPU) die, an input-output (IO) die, a dynamic random access memory (DRAM) controller, a static random-access memory (SRAM), a high bandwidth memory (HBM), an application processor (AP) die, an application specific integrated circuit (ASIC) die, the like, or any combination thereof.

The first semiconductor die 110 and the second semiconductor die 112 may include the same or different devices. For example, the first semiconductor die 110 may include a HBM, and the second semiconductor die 112 may include a SoC. It should be noted that the number of semiconductor dies is shown for illustrative purposes only, and more than two semiconductor dies may be disposed over the redistribution layer 104. In addition, one or more passive components (not illustrated) may be disposed over the redistribution layer 104, such as resistors, capacitors, inductors, or the like.

Then, an underfill material 114 is formed between the redistribution layer 104 and the first semiconductor die 110 and the second semiconductor die 112, in accordance with some embodiments. The underfill material 114 may surround the conductive bumps 108 and may fill in the gaps between them, providing structural support. In some embodiments, the underfill material 114 includes polymer, such as epoxy or another suitable material. The underfill material 114 may be dispensed with capillary force, and then may be cured through another suitable curing process.

Afterwards, a molding material 116 is formed over the redistribution layer 104, in accordance with some embodiments. The molding material 116 may surround the first semiconductor die 110 and the second semiconductor die 112 to protect these components from the environment, thereby preventing them from damage due to stress, chemicals, and moisture. The molding material 116 may be formed of a nonconductive material, including moldable polymer, epoxy, resin, the like, or a combination thereof.

Then, as illustrated in FIG. 1C, the structure shown in FIG. 1B is attached to a carrier wafer 118 and the carrier wafer 102 is removed, in accordance with some embodiments. The carrier wafer 118 may be similar to the carrier wafer 102, and a detailed description will not be repeated for the sake of brevity.

Afterwards, a plurality of conductive bumps 120 are disposed over the redistribution layer 104, in accordance with some embodiments. The conductive bumps 120 may include copper pillar bumps, microbumps, controlled collapse chip connection (C4) bumps, solder balls, ball grid array (BGA) balls, the like, or a combination thereof. The conductive bumps 120 may be formed of metal, such as tungsten, titanium, tantalum, ruthenium, cobalt, copper, aluminum, platinum, tin, silver, gold, the like, an alloy thereof, or a combination thereof. For example, as shown in FIG. 1C, the conductive bumps 120 include copper pillar bumps.

According to some embodiments, a bridge structure 200 is disposed over and electrically coupled to the redistribution layer 104. The first semiconductor die 110 may be electrically coupled to the second semiconductor die 112 through the bridge structure 200 and the redistribution layer 104. Compared to an approach that uses only the redistribution layer to realize a bridging function, the layer count of the redistribution layer 104 can be reduced, and the redistribution layer 104 is not necessary to be line width/line spacing less than 2 μm/2 μm. Therefore, yield improvement and cost saving can be achieved.

In addition, the normal redistribution layer fabrication can be adopted, and the manufacturing process may be a mature technology. That is, the semiconductor package structure 100 according to the present disclosure can be produced using existing flip chip machines and production lines, without the need of additional equipment or new production lines. Furthermore, the semiconductor package structure can be scaled to have multiple functions since a semiconductor component is disposed on a surface of the redistribution layer 104 where conductive bumps 120 are disposed, wherein the semiconductor component may be a semiconductor die or an integrated passive device (IPD). This enables the integration of diverse chiplets.

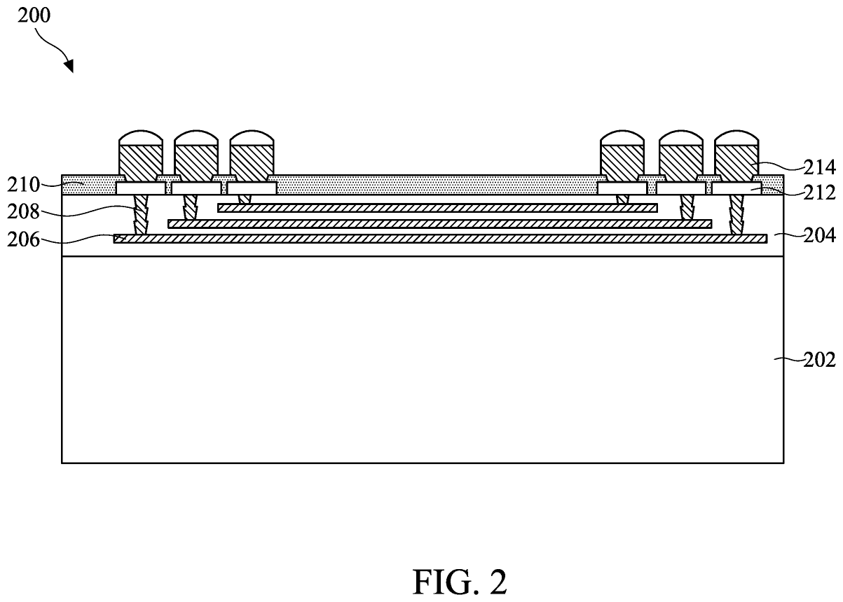

The bridge structure 200 may vertically overlap the first semiconductor die 110 and the second semiconductor die 112. Specifically, in the cross-sectional view, the bridge structure 200 may vertically overlap the first semiconductor die 110 and the second semiconductor die 112. Furthermore, as shown in FIG. 1C, the path in the redistribution layer 104 connecting the bridge structure 200 and the first semiconductor die 110, and the path in the redistribution layer 104 connecting the bridge structure 200 and the second semiconductor die 112 may be straight. The path in the redistribution layer 104 connecting the bridge structure 200 and the first semiconductor die 110 or the path in the redistribution layer 104 connecting the bridge structure 200 and the second semiconductor 120 may include at least two conductive vias and at least one conductive section, wherein the at least two conductive vias in the dielectric layers and the at least one conductive section in the conductive layer may be stacked substantially vertically in an alternative matter. In particular, as shown in FIG. 1C, a first conductive section in a first conductive layer in the redistribution layer 104 is on the first conductive via in a first dielectric layer in the redistribution layer 104 and is in direct contact with the first conductive via, wherein the first conductive via is connected to the conductive pads 121. A second conductive via is on the first conductive section in the first conductive layer and is in direct contact with the first conductive section. A second conductive section in a second conductive layer in the redistribution layer 104 is on the second conductive via in the second dielectric layer and is in direct contact with the second conductive via. A third conductive via is on the second conductive section in a second conductive layer and is in direct contact with the second conductive section, wherein the third conductive via is connected to the conductive pad 106. As shown in FIG. 1C, the conductive bump 108 connected to the first semiconductor die 110 and the conductive bump 108 connected to the second semiconductor die 112 may not be directly connected through the redistribution layer, but may be connected through the redistribution layer and the bridge structure. The conductive bump 108 connected to the first semiconductor die 110 is connected to one conductive bump on the bridge structure (for example, a conductive bump 214 in FIG. 2) through the redistribution layer, and the conductive bump 108 connected to the second semiconductor die 110 is connected to another conductive bump on the bridge structure (for example, a conductive bump 214 in FIG. 2) through the redistribution layer. The one conductive bump on the bridge structure is connected to another conductive bump on the bridge structure via an interconnect structure in the bridge structure.

The first semiconductor die 110, the second semiconductor die 112, and the bridge structure 200 shown in FIG. 1C connected by one row of microbumps respectively are for illustrative purposes only, and more than one rows of microbumps can be used to transmit the signals.

According to some embodiments, one or more semiconductor components 124 are disposed over the redistribution layer 104, in accordance with some embodiments. The semiconductor component 124 may include a semiconductor die, an integrated passive device (IPD), any suitable components, or a combination thereof. The semiconductor components 124 and bridge structure 200 may be electrically coupled to the redistribution layer 104 through a plurality of conductive pads 121 and a plurality of conductive bumps 122.

According to some embodiments, the conductive pads 121 may be formed over the first redistribution layer 104 and electrically coupled to the redistribution layer 104. The conductive pads 121 may be formed of metal, such as tungsten, titanium, tantalum, ruthenium, cobalt, copper, aluminum, platinum, tin, silver, gold, the like, an alloy thereof, or a combination thereof.

The conductive bumps 122 may include microbumps on the frontside of the semiconductor components 124 and the frontside of the bridge structure 200 and include solder materials connecting the microbumps and the conductive pads 121. The conductive bumps 108 may be formed of metal, such as tungsten, titanium, tantalum, ruthenium, cobalt, copper, aluminum, platinum, tin, silver, gold, the like, an alloy thereof, or a combination thereof.

Then, an underfill material 126 is formed between the redistribution layer 104 and the bridge structure 200 and between the redistribution layer 104 and the semiconductor component 124, in accordance with some embodiments. The underfill material 126 may surround the conductive pads 121 and the conductive bumps 122 and may fill in the gaps between them, providing structural support. In some embodiments, the underfill material 126 includes polymer, such as epoxy or another suitable material. The underfill material 126 may be dispensed with capillary force, and then may be cured through another suitable curing process.

Afterwards, a singulation process may be performed. The sidewall of the molding material 116 may be substantially coplanar with the sidewall of the redistribution layer 104. Then, the carrier wafer 118 may be removed. The top surface of the first semiconductor die 110 and the top surface of the second semiconductor die 112 may be exposed.

Afterwards, as illustrated in FIG. 1D, a substrate 128 is disposed under the redistribution layer 104, in accordance with some embodiments. The substrate 128 may have a wiring structure. In some embodiments, the wiring structure includes conductive pads, conductive vias, conductive lines, conductive pillars, the like, or a combination thereof. The wiring structure may be formed of metal, such as tungsten, titanium, tantalum, ruthenium, cobalt, copper, aluminum, platinum, tin, silver, gold, the like, an alloy thereof, or a combination thereof.

The substrate 128 may be electrically coupled to the conductive bumps 120. The substrate 128 may be spaced apart from the bridge structure 200 and the semiconductor component 124. The distance D between the bridge structure 200 and the substrate 128 may be greater than 0. For example, the distance D between the bridge structure 200 and the substrate 128 may be greater than 0 and less than about 30 μm, such as about 20 μm.

The bridge structure 200 has a top surface facing to the redistribution layer 104 and a bottom surface facing away from the redistribution layer 104. The bottom portion of the conductive bumps 120 may be lower than the bottom surface of the bridge structure 200 and the bottom surface of the semiconductor component 124. The bridge structure 200 is between two conductive bumps 120 in the cross-sectional view. The semiconductor component 124 is between two conductive bumps 120 in the cross-sectional view.

Then, an underfill material 130 is formed between the redistribution layer 104 and the substrate 128, in accordance with some embodiments. The underfill material 130 may surround the conductive bumps 120, the semiconductor component 124, and the bridge structure 200, and may fill in the gaps between them, providing structural support. The underfill material 130 may extend between the substrate 128 and the bridge structure 200 and between the substrate 128 and the semiconductor component 124. In some embodiments, the underfill material 130 includes polymer, such as epoxy or another suitable material. The underfill material 130 may be dispensed with capillary force, and then may be cured through another suitable curing process.

A plurality of conductive bumps 132 are disposed below the substrate 128, in accordance with some embodiments. The conductive bumps 132 may be formed of metal, such as tungsten, titanium, tantalum, ruthenium, cobalt, copper, aluminum, platinum, tin, silver, gold, the like, an alloy thereof, or a combination thereof.

FIG. 2 is a cross-sectional view of a bridge structure 200 in accordance with some embodiments of the present disclosure. Additional features can be added to the bridge structure 200. Some of the features described below can be replaced or eliminated for different embodiments. To simplify the diagram, only a portion of the bridge structure 200 is illustrated.

As illustrated in FIG. 2, the bridge structure 200 includes a semiconductor substrate 202, in accordance with some embodiments. The semiconductor substrate 202 may be formed of any suitable semiconductor material, including silicon, germanium, silicon carbon, silicon germanium, gallium arsenide, indium arsenide, indium phosphide, the like, or a combination thereof. The semiconductor substrate 202 may include a bulk semiconductor or a composite substrate formed of different materials.

A dielectric layer 204 is disposed over the semiconductor substrate 202, and an interconnect structure is disposed in a dielectric layer 204, in accordance with some embodiments. The sidewall of the dielectric layer 204 may be substantially coplanar with the sidewall of the semiconductor substrate 202. The interconnect structure may include horizontal interconnects, such as conductive wires 206, and vertical interconnects, such as conductive vias 208.

The interconnect structure may be formed of metal, such as tungsten, titanium, tantalum, ruthenium, cobalt, copper, aluminum, platinum, tin, silver, gold, the like, an alloy thereof, or a combination thereof. The dielectric layer 204 may be formed of polymer, including polyimide (PI), polybenzoxazole (PBO), benzocyclobutene (BCB), epoxy, the like, or a combination thereof. Alternatively, the dielectric layer 204 may be formed of silicon oxide, silicon nitride, silicon oxynitride, the like, or a combination thereof. It should be noted that three conductive wires 206 are shown for illustrative purposes only, and the interconnect structure may include more or less conductive wires 206.

According to some embodiments, a plurality of conductive pads 212 are formed over the dielectric layer 204 and electrically coupled to the conductive vias 208. The conductive pads 212 may be formed of metal, such as tungsten, titanium, tantalum, ruthenium, cobalt, copper, aluminum, platinum, tin, silver, gold, the like, an alloy thereof, or a combination thereof.

According to some embodiments, a passivation layer 210 is disposed over the dielectric layer 204 and covers the top surface of the dielectric layer 204. The conductive pads 212 are exposed from the passivation layer 210. The passivation layer 210 may be formed of polymer, including polyimide (PI), polybenzoxazole (PBO), benzocyclobutene (BCB), epoxy, the like, or a combination thereof. Alternatively, the passivation layer 210 may be formed of silicon oxide, silicon nitride, silicon oxynitride, the like, or a combination thereof. The sidewall of the passivation layer 210 may be substantially coplanar with the sidewall of the dielectric layer 204.

According to some embodiments, a plurality of conductive bumps 214 are formed over the conductive pads 212. The bottom portion of the conductive bumps 214 may be surrounded by the passivation layer 210 and connected to the conductive pads 212. The conductive bumps 214 may include microbumps over the conductive pads 212 and solder materials over the microbumps. The conductive bumps 214 may be formed of metal, such as tungsten, titanium, tantalum, ruthenium, cobalt, copper, aluminum, platinum, tin, silver, gold, the like, an alloy thereof, or a combination thereof.

The conductive bumps 214 on the left may connect to the first semiconductor die 110, and conductive bumps 214 on the right may connect to the second semiconductor die 112. For example, as shown in FIG. 2, three conductive bumps 214 on the left may connect to three conductive pads 111 of the first semiconductor die 110, and three conductive bumps 214 on the right may connect to three conductive pads 111 of the second semiconductor die 112. More or less conductive bumps 214 and conductive pads 111 may be adopted. In an embodiment, one conductive bump 214 may be connected to only one conductive pad 111 of the first semiconductor die 110 or the second semiconductor die 112. Alternatively, one conductive bump 214 may be connected to more than one conductive pad 111 of the first semiconductor die 110 or the second semiconductor die 112.

The semiconductor package structure 100 may be used for high performance computing or AI.

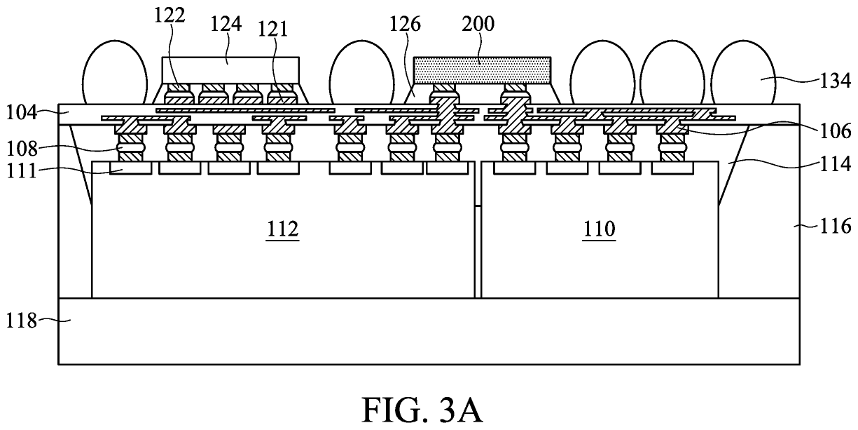

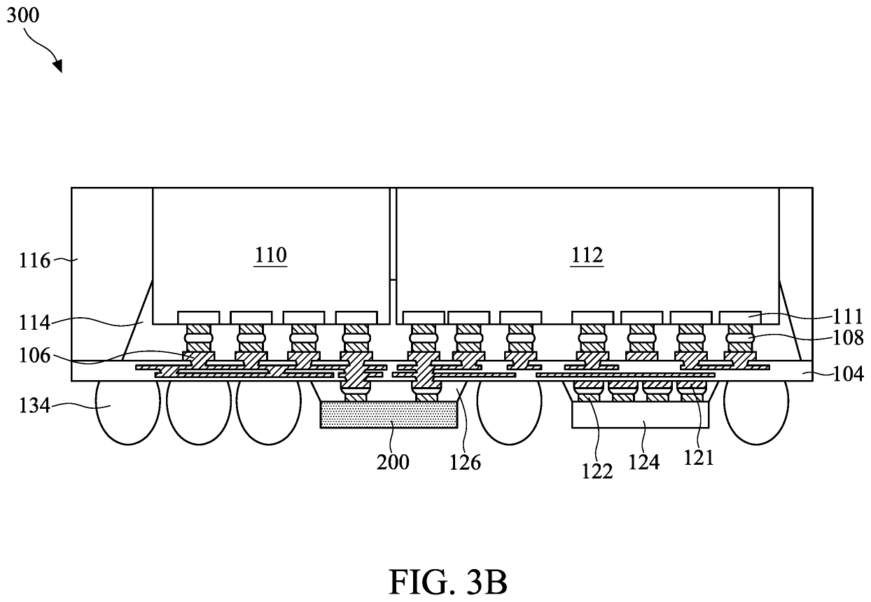

FIGS. 3A and 3B are cross-sectional views of various stages of manufacturing a semiconductor package structure 300 in accordance with some embodiments of the present disclosure. FIG. 3A is subsequent to the step of the process that is illustrated in FIG. 1B, and the same or similar reference numbers are used to depict the same or similar components as those of the semiconductor package structure 100, so for the sake of simplicity, those components will not be discussed in detail again.

As illustrated in FIG. 3A, a plurality of conductive bumps 134 are disposed over the redistribution layer 104 and connected to the redistribution layer 104, in accordance with some embodiments. The conductive bumps 134 may be formed of metal, such as tungsten, titanium, tantalum, ruthenium, cobalt, copper, aluminum, platinum, tin, silver, gold, the like, an alloy thereof, or a combination thereof. In the embodiments, the conductive bumps 134 include ball grid array (BGA) balls.

According to some embodiments, a bridge structure 200 and one or more semiconductor components 124 are disposed over and electrically coupled to the redistribution layer 104. The bridge structure 200 and the semiconductor component 124 may be disposed between conductive bumps 134. Then, an underfill material 126 may be formed between the redistribution layer 104 and the bridge structure 200 and between the redistribution layer 104 and the semiconductor component 124. The bridge structure 200, the semiconductor component 124, and the underfill material 126 have been described above with reference to FIG. 1C, and will not be repeated.

Afterwards, a singulation process may be performed. The sidewall of the molding material 116 may be substantially coplanar with the sidewall of the redistribution layer 104. Then, the carrier wafer 118 may be removed. The top surface of the first semiconductor die 110 and the top surface of the second semiconductor die 112 may be exposed.

As shown in FIG. 3B, the bridge structure 200 and the semiconductor component 124 are exposed. The bottom portion of the conductive bumps 134 may be lower than the bottom surface of the bridge structure 200 and the bottom surface of the semiconductor component 124.

The semiconductor package structure 300 may be used for a notebook or a laptop.

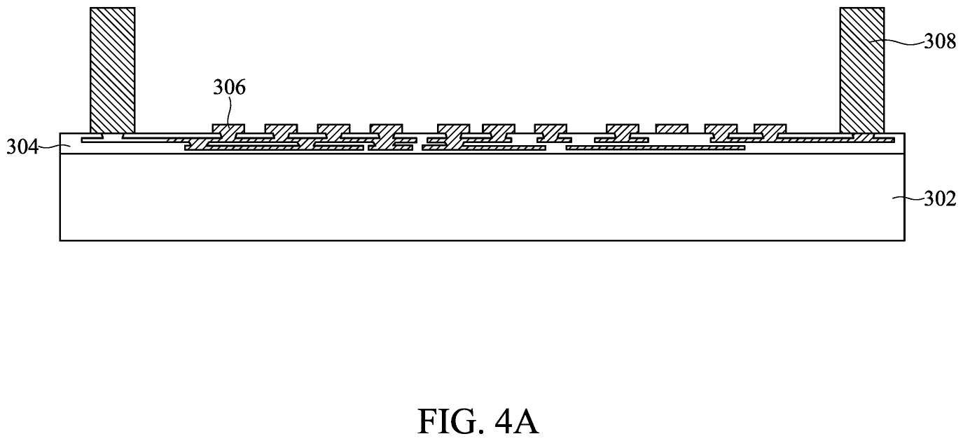

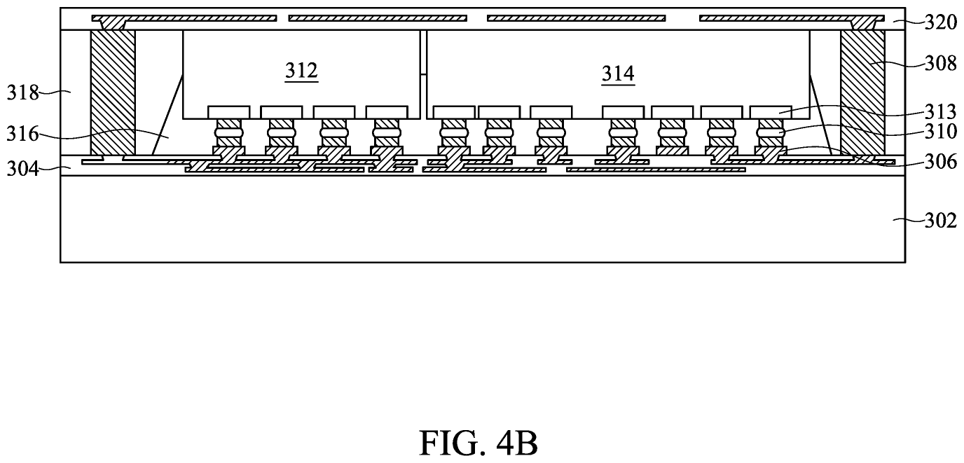

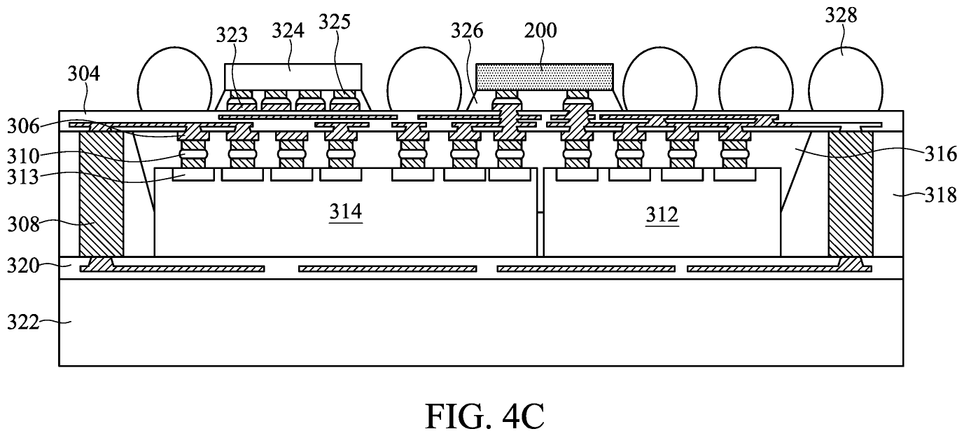

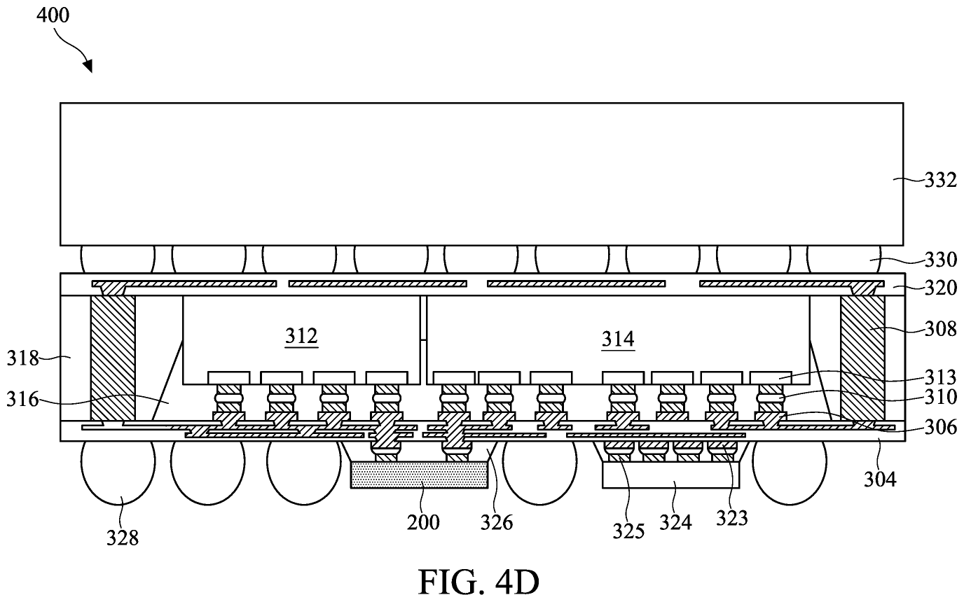

FIGS. 4A-4D are cross-sectional views of various stages of manufacturing a semiconductor package structure 400 in accordance with some embodiments of the present disclosure. Additional features can be added to the semiconductor package structure 400. Some of the features described below can be replaced or eliminated for different embodiments. To simplify the diagram, only a portion of the semiconductor package structure 400 is illustrated.

As shown in FIG. 4A, a first redistribution layer 304 is formed over a carrier wafer 302, in accordance with some embodiments. The carrier wafer 302 may be a glass carrier substrate, a ceramic carrier substrate, or another suitable carrier substrate.

The first redistribution layer 304 may include a plurality of dielectric layers and at least one conductive layer. The first redistribution layer 304 may include a plurality of conductive vias disposed in the dielectric layer and connected to a conductive wire or a conductive section in the conductive layer. The precise patterns of the conductive layer are defined using photolithography technology, followed by an etching process to remove the excess metal, leaving the desired conductive wires and the conductive sections. For example, the first redistribution layer 304 includes two or three conductive layers. The conductive layers may be formed of metal, such as tungsten, titanium, tantalum, ruthenium, cobalt, copper, aluminum, platinum, tin, silver, gold, the like, an alloy thereof, or a combination thereof. The dielectric layers may be formed of polymer, including polyimide (PI), polybenzoxazole (PBO), benzocyclobutene (BCB), epoxy, the like, or a combination thereof. Alternatively, the dielectric layers may be formed of silicon oxide, silicon nitride, silicon oxynitride, the like, or a combination thereof.

Then, a plurality of conductive pads 306 and a plurality of conductive pillars 308 are formed over the first redistribution layer 304 and electrically coupled to the first redistribution layer 304, in accordance with some embodiments. Specifically, the plurality of conductive pads 306 and the plurality of conductive pillars 308 are connected to the conductive vias in the first redistribution layer 304. The conductive pads 306 and the conductive pillars 308 may be each formed of metal, such as tungsten, titanium, tantalum, ruthenium, cobalt, copper, aluminum, platinum, tin, silver, gold, the like, an alloy thereof, or a combination thereof.

Afterwards, as illustrated in FIG. 4B, a first semiconductor die 312 and a second semiconductor die 314 are disposed over the first redistribution layer 304, in accordance with some embodiments. The first semiconductor die 312 and the second semiconductor die 314 may include a plurality of conductive pads 313 on the frontside of the first semiconductor die 312 and the frontside of the second semiconductor die 314. The conductive pads 313 may be formed of metal, such as tungsten, titanium, tantalum, ruthenium, cobalt, copper, aluminum, platinum, tin, silver, gold, the like, an alloy thereof, or a combination thereof.

The first semiconductor die 312 and the second semiconductor die 314 may be electrically coupled to the first redistribution layer 304 through a plurality of conductive bumps 310 and the conductive pads 306. In some embodiments, the conductive bumps 310 include microbumps on the conductive pads 313 and microbumps on the conductive pads 306 and include solder materials connecting the microbumps on the conductive pads 313 and the microbumps on the conductive pads 306. The conductive bumps 310 may be formed of metal, such as tungsten, titanium, tantalum, ruthenium, cobalt, copper, aluminum, platinum, tin, silver, gold, the like, an alloy thereof, or a combination thereof.

In some embodiments, the first semiconductor die 312 and the second semiconductor die 314 each includes a system-on-chip (SoC) die, a logic device, a memory device, a radio frequency (RF) device, the like, or any combination thereof. For example, the first semiconductor die 312 and the second semiconductor die 314 may each include a micro control unit (MCU) die, a microprocessor unit (MPU) die, a power management integrated circuit (PMIC) die, a radio frequency front end (RFFE) die, an accelerated processing unit (APU) die, a central processing unit (CPU) die, a graphics processing unit (GPU) die, an input-output (IO) die, a dynamic random access memory (DRAM) controller, a static random-access memory (SRAM), a high bandwidth memory (HBM), an application processor (AP) die, an application specific integrated circuit (ASIC) die, the like, or any combination thereof.

The first semiconductor die 312 and the second semiconductor die 314 may include the same or different devices. For example, the first semiconductor die 312 may include a HBM, and the second semiconductor die 314 may include a SoC. It should be noted that the number of semiconductor dies is shown for illustrative purposes only, and more than two semiconductor dies may be disposed over the first redistribution layer 304. In addition, one or more passive components (not illustrated) may be disposed over the first redistribution layer 304, such as resistors, capacitors, inductors, the like, or a combination thereof.

Then, an underfill material 316 is formed between the first redistribution layer 304 and the first semiconductor die 312 and the second semiconductor die 314, in accordance with some embodiments. The underfill material 316 may surround the conductive bumps 310 and may fill in the gaps between them, providing structural support. In some embodiments, the underfill material 316 includes polymer, such as epoxy or another suitable material. The underfill material 316 may be dispensed with capillary force, and then may be cured through another suitable curing process.

Afterwards, a molding material 318 is formed over the first redistribution layer 304, in accordance with some embodiments. The molding material 318 may surround the first semiconductor die 312, the second semiconductor die 314, and the conductive pillars 308 to protect these components from the environment, thereby preventing them from damage due to stress, chemicals, and moisture. The molding material 318 may be formed of a nonconductive material, including moldable polymer, epoxy, resin, the like, or a combination thereof.

Then, a second redistribution layer 320 is formed over the molding material 318 and electrically coupled to the first redistribution layer 304 through the conductive pillars 308, in accordance with some embodiments. The second redistribution layer 320 may have a plurality of dielectric layers and at least one conductive layer. The second redistribution layer 320 may have a plurality of conductive vias disposed in the dielectric layer and connected to a conductive wire in the conductive layer. The precise patterns of the conductive layer are defined using photolithography technology, followed by an etching process to remove the excess metal, leaving the desired conductive wires. The conductive layers and the dielectric layers of the second redistribution layer 320 may be similar to that of the first redistribution layer 304, and will not be repeated.

The number of the conductive layers of the second redistribution layer 320 may be fewer than that of the first redistribution layer 304. For example, the second redistribution layer 320 may include 1 to 3 conductive layers. The thickness of the second redistribution layer 320 may be less than that of the first redistribution layer 304.

Afterwards, as illustrated in FIG. 4C, the structure shown in FIG. 4B is attached to a carrier wafer 322 and the carrier wafer 302 is removed, in accordance with some embodiments. The carrier wafer 322 may be similar to the carrier wafer 302, and will not be repeated.

Then, a plurality of conductive bumps 328 are disposed over the first redistribution layer 304, in accordance with some embodiments. The conductive bumps 328 may include copper pillar bumps, microbumps, controlled collapse chip connection (C4) bumps, solder balls, ball grid array (BGA) balls, the like, or a combination thereof. The conductive bumps 328 may be formed of metal, such as tungsten, titanium, tantalum, ruthenium, cobalt, copper, aluminum, platinum, tin, silver, gold, the like, an alloy thereof, or a combination thereof. For example, as shown in FIG. 4C, the conductive bumps 328 include BGA balls.

According to some embodiments, a bridge structure 200 is disposed over and electrically coupled to the first redistribution layer 304. The first semiconductor die 312 may be electrically coupled to the second semiconductor die 314 through the bridge structure 200 and the first redistribution layer 304. As a result, the layer count of the first redistribution layer 304 can be reduced, and the first redistribution layer 304 is not necessary to be line width/line spacing less than 2 μm/2 μm. Therefore, yield improvement and cost saving can be achieved. In addition, the normal redistribution layer fabrication can be adopted. Furthermore, the semiconductor package structure can be scaled to have multiple functions since a semiconductor component is disposed on a surface of the first redistribution layer 304 where conductive bumps 328 are disposed, wherein the semiconductor component may be a semiconductor die and/or an IPD.

The bridge structure 200 may vertically overlap the first semiconductor die 312 and the second semiconductor die 314. As shown in FIG. 4C, the path in the first redistribution layer 304 connecting the bridge structure 200 and the first semiconductor die 312 may be straight, and the path in the first redistribution layer 304 connecting the bridge structure 200 and the second semiconductor die 314 may be straight. The first semiconductor die 312, the second semiconductor die 314, and the bridge structure 200 shown in FIG. 4C connected by one row of microbumps respectively is for illustrative purposes only, and more than one rows of microbumps can be used to transmit the signals.

According to some embodiments, one or more semiconductor components 324 are disposed over the first redistribution layer 304, in accordance with some embodiments. The semiconductor component 324 may include a semiconductor die, an integrated passive device (IPD), any suitable components, or a combination thereof. The semiconductor components 324 and bridge structure 200 may be electrically coupled to the first redistribution layer 304 through a plurality of conductive pads 323 and a plurality of conductive bumps 325.

According to some embodiments, the conductive pads 323 may be formed over the first redistribution layer 304 and electrically coupled to the first redistribution layer 304. The conductive bumps 325 may include microbumps on the frontside of the semiconductor components 324 and the frontside of the bridge structure 200 and include solder materials connecting the microbumps and the conductive pads 323. The conductive pads 323 and the conductive bumps 325 may be similar to the conductive pads 121 and the conductive bumps 122 as illustrated in FIG. 1C, and will not be repeated.

Then, an underfill material 326 is formed between the first redistribution layer 304 and the bridge structure 200 and between the first redistribution layer 304 and the semiconductor component 324, in accordance with some embodiments. The underfill material 326 may surround the conductive pads 323 and the conductive bumps 325, and may fill in the gaps between them, providing structural support. The underfill material 326 may be similar to the underfill material 126 as illustrated in FIG. 1C, and will not be repeated.

Afterwards, a singulation process may be performed. The sidewall of the molding material 318 may be substantially coplanar with the sidewall of the first redistribution layer 304 and may be substantially coplanar with the sidewall of the second redistribution layer 320. Then, the carrier wafer 322 may be removed. The top surface of the second redistribution layer 320 may be exposed.

Then, as illustrated in FIG. 4D, a package structure 332 is stacked over the second redistribution layer 320, and a semiconductor package structure 400 is formed, in accordance with some embodiments. The package structure 322 may include one or more semiconductor dies. For example, the semiconductor dies may include memory dies, such as a dynamic random access memory (DRAM), or another suitable device. The package structure 322 may also include one or more passive components (not illustrated), including resistors, capacitors, or inductors.

The package structure 322 includes a plurality of conductive bumps 330 electrically coupled to the second redistribution layer 320, in accordance with some embodiments. The conductive bumps 330 may include microbumps, controlled collapse chip connection (C4) bumps, solder balls, ball grid array (BGA) balls, the like, or a combination thereof. The conductive bumps 328 may be formed of metal, such as tungsten, titanium, tantalum, ruthenium, cobalt, copper, aluminum, platinum, tin, silver, gold, the like, an alloy thereof, or a combination thereof.

The signal of the semiconductor dies in the package structure 322 may be transmitted to the first semiconductor die 312 and the second semiconductor die 314 through the conductive bumps 330, the second redistribution layer 320, the conductive pillars 308, and the first redistribution layer 304.

The semiconductor package structure 400 may be used for a mobile device or a wearable device.

In summary, the semiconductor package structure according to the present disclosure includes a bridge structure disposed on a surface of a redistribution layer where conductive bumps are disposed, and one semiconductor die is electrically coupled to another semiconductor die through the redistribution layer and the bridge structure. As a result, the layer count of the redistribution layer for electrically coupling semiconductor dies can be reduced, and the redistribution layer is not necessary to be line width/line spacing less than 2 μm/2 μm. In addition, the normal redistribution layer fabrication can be adopted. Therefore, yield improvement, cost saving and scalability of the semiconductor package structure can be achieved.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A semiconductor package structure, comprising:
a first redistribution layer;
a first semiconductor die and a second semiconductor die disposed over the first redistribution layer;
a bridge structure disposed under the first redistribution layer, wherein the first semiconductor die is electrically coupled to the second semiconductor die through the first redistribution layer and the bridge structure; and
a plurality of conductive bumps disposed under the first redistribution layer and coupled to the first redistribution layer, wherein the bridge structure is disposed between at least two of the conductive bumps.

2. The semiconductor package structure as claimed in claim 1, wherein a path in the first redistribution layer connecting the bridge structure and the first semiconductor die or the second semiconductor die comprises at least two conductive vias and at least one conductive section, wherein the at least two conductive vias and the at least one conductive section are stacked substantially vertically in an alternative matter.

3. The semiconductor package structure as claimed in claim 1, further comprising a substrate disposed under the bridge structure and electrically coupled to the conductive bumps.

4. The semiconductor package structure as claimed in claim 3, wherein a distance between the bridge structure and the substrate is greater than 0.

5. The semiconductor package structure as claimed in claim 3, further comprising an underfill material surrounding the bridge structure and the conductive bumps.

6. The semiconductor package structure as claimed in claim 1, further comprising:
a second redistribution layer disposed over the first semiconductor die and the second semiconductor die;
a molding material disposed between the first redistribution layer and the second redistribution layer and surrounding the first semiconductor die and the second semiconductor die; and
a conductive pillar disposed in the molding material and electrically coupling the first redistribution layer and the second redistribution layer.

7. The semiconductor package structure as claimed in claim 1, wherein a bottom surface of the bridge structure is exposed, and the bottom surface of the bridge structure is a surface facing away from the first redistribution layer.

8. The semiconductor package structure as claimed in claim 1, further comprising a third semiconductor die and/or an integrated passive device (IPD) disposed under the first redistribution layer and electrically coupled to the first redistribution layer.

9. The semiconductor package structure as claimed in claim 1, wherein a bottom portion of the conductive bumps is lower than a bottom surface of the bridge structure, and the bottom surface of the bridge structure is a surface facing away from the first redistribution layer.

10. The semiconductor package structure as claimed in claim 1, further comprising:
a first conductive bump disposed between the redistribution layer and the first semiconductor die and coupled to the first redistribution layer and the first semiconductor die; and
a second conductive bump disposed between the first redistribution layer and the second semiconductor die and coupled to the first redistribution layer and the second semiconductor die,
wherein the first semiconductor die is coupled to a third conductive bump on the bridge structure through the first conductive bump and the first redistribution layer, and the second semiconductor die is coupled to a fourth conductive bump on the bridge structure through the second conductive bump and the first redistribution layer, and the third conductive bump on the bridge structure is coupled to the fourth conductive bump through an internal connection structure within the bridge structure.

11. The semiconductor package structure as claimed in claim 1, wherein the conductive bumps comprise copper pillar bumps, microbumps, controlled collapse chip connection (C4) bumps, solder balls, ball grid array (BGA) balls, or a combination thereof.

12. A semiconductor package structure, comprising:
a substrate;
a redistribution layer;
a plurality of conductive bumps disposed between the substrate and the redistribution layer and electrically coupling the substrate and the redistribution layer;
a bridge structure disposed between the substrate and the redistribution layer and electrically coupled to the redistribution layer, wherein the bridge structure is spaced apart from the substrate; and
a first semiconductor die and a second semiconductor die disposed over the redistribution layer, wherein the first semiconductor die is electrically coupled to the second semiconductor die through the first redistribution layer and the bridge structure.

13. The semiconductor package structure as claimed in claim 12, further comprising an underfill material disposed between the bridge structure and the substrate.

14. The semiconductor package structure as claimed in claim 12, further comprising a third semiconductor die and/or an integrated passive device (IPD) disposed between the substrate and the redistribution layer and electrically coupled to the redistribution layer.

15. The semiconductor package structure as claimed in claim 12, wherein the bridge structure vertically overlaps the first semiconductor die and the second semiconductor die.

16. The semiconductor package structure as claimed in claim 12, wherein the bridge structure comprises:
a semiconductor substrate;
an interconnect structure disposed in a dielectric layer over the semiconductor substrate; and
a plurality of conductive bumps electrically coupled to the interconnect structure and the redistribution layer.

17. A semiconductor package structure, comprising:
a first redistribution layer;
a first semiconductor die and a second semiconductor die disposed over the first redistribution layer;
a molding material surrounding the first semiconductor die and the second semiconductor die; and
a bridge structure disposed under the first redistribution layer and electrically coupling the first semiconductor die and the second semiconductor die, wherein a bottom surface of the bridge structure is exposed, wherein the bottom surface of the bridge structure is a surface facing away from the first redistribution layer.

18. The semiconductor package structure as claimed in claim 17, further comprising an integrated passive device (IPD) disposed under and electrically coupled to the first redistribution layer, wherein a bottom surface of the IPD is exposed.

19. The semiconductor package structure as claimed in claim 18, further comprising a first conductive bump disposed between the bridge structure and the IPD.

20. The semiconductor package structure as claimed in claim 19, further comprising:
a second redistribution layer disposed over the molding material; and
a second conductive bump disposed over the second redistribution layer and connected to the second redistribution layer.
